(19) United States
(12) Patent Application Publication
(10) Pub. No.: US 2025/0358982 A1
(43) Pub. Date: Nov. 20, 2025

(54) TECHNOLOGIES FOR MONITORING LIQUID COOLING LOOPS FOR HIGH-PERFORMANCE COMPUTING SYSTEMS

(71) Applicant: ECOLAB USA Inc., St. Paul, MN (US)

(72) Inventors: Robert M. LOWE, Chicago, IL (US); Robert S. WALICKI, Oak Park, IL (US); Michael J. MURCIA, Sycamore, IL (US); Paul OVERBECK, St. Paul, MN (US)

(73) Assignee: ECOLAB USA Inc., St. Paul, MN (US)

(21) Appl. No.: 19/210,547

(22) Filed: May 16, 2025

Related U.S. Application Data
(60) Provisional application No. 63/649,128, filed on May 17, 2024.
(60) Provisional application No. 63/649,259, filed on May 17, 2024.
(60) Provisional application No. 63/721,976, filed on Nov. 18, 2024.

(51) Int. Cl. H05K 7/20

(52) U.S. Cl. CPC H05K 7/20836; H05K 7/20772

(57) ABSTRACT

A system includes a coolant blade adapted to be received in a high-performance computing blade enclosure. The coolant blade includes a liquid cooling conduit and one or more liquid sensors fluidly coupled to the liquid cooling conduit. The liquid cooling conduit is removably coupled to a secondary cooling loop of the high-performance computing blade enclosure when the coolant blade is received in the high-performance computing blade enclosure. A controller receives sensor data indicative of one or more properties of liquid coolant within the liquid cooling conduit from at least one of the one or more sensors.

### TECHNICAL FIELD

The present disclosure generally relates to cooling technologies for computer systems. More particularly, the disclosure relates to liquid cooling systems for high-performance computing systems.

### BACKGROUND

Large computer systems, such as supercomputers, high-performance computing (HPC) systems, data centers, enterprise systems, and other large computer systems generate significant amounts of waste heat that must be managed. Traditionally, computer systems were air-cooled; however, many modern supercomputers and other large computer systems use liquid cooling systems. Liquid cooling may increase cooling efficiency and effectiveness as compared to air cooling, especially for extremely power-dense computing systems. Typical liquid cooling systems for large computing systems include a closed loop that is pressurized with coolant, such as water or a water/propylene glycol mixture.

In use, the coolant included in such a closed loop cooling system for computer systems may become degraded, contaminated, or otherwise change over time. Liquid cooling systems for computing systems are typically manually inspected and serviced.

### BRIEF SUMMARY

According to certain aspects of the present disclosure, a system for computing device cooling liquid monitoring is provided. The system comprises a liquid monitoring system adapted to be coupled to a secondary coolant loop, wherein the secondary coolant loop connects a high-performance computing system and a heat exchanger. The liquid monitoring system comprises a liquid cooling conduit in fluid communication with the secondary coolant loop and one or more sensors fluidly coupled to the liquid cooling conduit and/or the secondary coolant loop. The system also comprises a controller operatively coupled to at least one of the one or more sensors. The system may comprise more than one liquid cooling conduit. Each liquid cooling conduit may be in fluid communication with the secondary coolant loop and each liquid cooling conduit may comprise one or more sensors fluidly coupled thereto.

The secondary coolant loop and/or the liquid cooling conduit may comprise a liquid coolant. The liquid coolant may comprise water and/or a glycol.

The system may further comprise a quick connect that removably couples any or all of the one or more sensors to the liquid cooling conduit and/or the secondary coolant loop. The system may further comprise a port coupled to the liquid cooling conduit, wherein the port is adapted to connect a portable bank of sensors to the liquid cooling conduit and/or the secondary coolant loop. The system may further comprise a modular sensor system, wherein the one or more sensors are included in the modular sensor system. In some embodiments, the one or more sensors comprise calibration-free sensors.

The one or more sensors may comprise a conductivity sensor, a turbidity sensor, a pH sensor, a temperature sensor, a flow rate sensor, a fluorometer, a color sensor, a dissolved oxygen sensor, a pressure sensor, a differential pressure sensor, a vibration sensor, an IR light sensor, an alkalinity sensor, an entrained air sensor, a particle size sensor, a sensor for measuring glycol wt. %, or any combination thereof. In some embodiments, the one or more sensors comprise a microbiology sensor, an oxidation-reduction potential sensor, and/or a device for measuring organic and/or inorganic fouling.

The one or more sensors may comprise a color sensor and the controller may be configured to monitor color of the liquid coolant and/or an additive in the liquid coolant in the secondary coolant loop and/or the liquid cooling conduit with the color sensor. The additive may be selected from the group consisting of a corrosion inhibitor, a scale inhibitor, a buffer, a dispersant, a biocide, a scouring agent, a viscosity modifier, a heat transfer additive, a surfactant, a glycol, water, and any combination thereof.

The system may comprise a plurality of leak sensors and the controller may be configured to perform multi-point leak detection.

The one or more sensors of the system may comprise an infrared (IR) light sensor and the controller may be configured to monitor for organic contamination in the secondary coolant loop and/or the liquid cooling conduit with the IR light sensor.

The one or more sensors may comprise an alkalinity sensor and the controller may be configured to perform real-time alkalinity monitoring of the liquid coolant with the alkalinity sensor. The controller may be configured to perform real-time alkalinity monitoring of the liquid coolant by, for example, an online titration.

The controller may be configured to monitor air entrainment within the secondary coolant loop and/or the liquid cooling conduit with the one or more sensors.

The system may comprise one or more additional sensors coupled to the heat exchanger and/or the secondary coolant loop.

The controller may be configured to monitor performance of the heat exchanger with the one or more additional sensors.

In some embodiments, the one or more additional sensors may comprise a vibration sensor, a pressure sensor, a temperature sensor, a flow rate sensor, or any combination thereof. In some embodiments, the one or more sensors comprise a refractometer to measure a weight percent of a component of the liquid coolant, such as a glycol, a corrosion inhibitor, or any other additive disclosed herein.

The heat exchanger may comprise a pump and the controller may be configured to predict pump failure.

The controller may be configured to monitor air-side temperature, dewpoint, and/or operational modifications of the high-performance computing system with the one or more additional sensors.

The controller may be configured to perform real-time monitoring of the heat exchanger with the one or more additional sensors. The controller may be configured to predict fluid life of the liquid coolant with the one or more sensors. The controller may be configured to determine current heat load requirements of the high-performance computing system and modify flow rate of the heat exchanger and/or the liquid coolant in response to a determination of the current heat load requirements. The controller may be configured to transmit the sensor data to a remote device and/or store the sensor data. The controller may be configured to receive a control input from a user interface device of the controller and store the control input with reference to the sensor data. The controller may be configured to compare the sensor data to one or more predetermined sensor data values and optionally activate an alarm in response to comparison of the sensor data to the one or more predetermined sensor data values. The controller may be configured to add an additive to the secondary coolant loop in response to comparison of the sensor data to the one or more predetermined sensor data values.

In some embodiments, the one or more predetermined sensor data values comprise a minimum glycol weight percentage and the additive comprises a glycol.

The additive may comprise a dispersant, a surfactant, a heat transfer additive, an inhibitor, a biocide, a scouring agent, a glycol, water, or any combination thereof.

The controller may be configured to discharge all or at least a portion of the liquid coolant from the secondary coolant loop coupled to the liquid cooling conduit based on the sensor data and add additional liquid coolant to the secondary coolant loop in response to the discharge of the liquid coolant.

The controller may be configured to evaluate a plurality of characteristics of the liquid coolant with an artificial intelligence model to determine health of the liquid coolant, wherein the artificial intelligence model is locally executed by the controller or remotely hosted by a remote computing device.

The system may further comprise a cooling distribution unit and the cooling distribution unit includes the heat exchanger.

The present disclosure also provides a system for computing device cooling liquid monitoring. The system comprises a liquid cooling conduit in fluid communication with an inlet and an outlet. The inlet and the outlet are adapted to be coupled to a secondary coolant loop, wherein the secondary coolant loop connects a high-performance computing system and a heat exchanger. The system also comprises one or more sensors fluidly coupled to the liquid cooling conduit and/or the secondary coolant loop, wherein the one or more sensors are configured to generate sensor data indicative of one or more properties of a liquid coolant within the liquid cooling conduit and/or the secondary coolant loop. Additionally, the system comprises a controller operatively coupled to at least one of the one or more sensors and configured to receive the sensor data indicative of the one or more properties of the liquid coolant. The liquid coolant may comprise water and/or a glycol.

The system may comprise a quick connect that removably couples any or all of the one or more sensors to the liquid cooling conduit.

The system may comprise a port coupled to the liquid cooling conduit and the port may be adapted to connect a portable bank of sensors to the liquid cooling conduit. The system may comprise a modular sensor system and the one or more sensors may be included in the modular sensor system. The one or more sensors may comprise calibration-free sensors.

The one or more sensors may comprise a conductivity sensor, a turbidity sensor, a pH sensor, a temperature sensor, a flow rate sensor, a fluorometer, a color sensor, a dissolved oxygen sensor, a pressure sensor, a differential pressure sensor, a vibration sensor, an IR light sensor, an alkalinity sensor, an entrained air sensor, a particle size sensor, a sensor for measuring glycol wt. %, or any combination thereof. In some embodiments, the one or more sensors comprise a microbiology sensor, an oxidation-reduction potential sensor, and/or a device for measuring organic and/or inorganic fouling.

The one or more sensors may comprise a color sensor and the controller may be configured to monitor color of the liquid coolant and/or an additive in the liquid coolant in the secondary coolant loop and/or the liquid cooling conduit with the color sensor. The additive may be selected from the group consisting of a corrosion inhibitor, a scale inhibitor, a buffer, a dispersant, a biocide, a scouring agent, a viscosity modifier, a heat transfer additive, a surfactant, a glycol, water, and any combination thereof.

The system may comprise a plurality of leak sensors and the controller may be configured to perform multi-point leak detection.

The one or more sensors of the system may comprise an IR light sensor and the controller is configured to monitor for organic contamination in the secondary coolant loop and/or the liquid cooling conduit with the IR light sensor.

The one or more sensors may comprise an alkalinity sensor and the controller may be configured to perform real-time alkalinity monitoring of the liquid coolant with the alkalinity sensor.

In some embodiments, the one or more properties of the liquid coolant are selected from the group consisting of conductivity, turbidity, temperature, entrained air, pH, percent glycol, fluorescence, color, dissolved oxygen, alkalinity, and any combination thereof. These properties may be measured/determined using a sensor disclosed herein and/or a device other than a sensor.

The controller may be configured to perform real-time alkalinity monitoring of the liquid coolant by, for example, an online titration.

The controller may be configured to monitor air entrainment within the secondary coolant loop and/or the liquid cooling conduit with the one or more sensors.

The system may comprise one or more additional sensors coupled to the heat exchanger and/or the secondary coolant loop. The controller may be configured to monitor performance of the heat exchanger with the one or more additional sensors.

The one or more additional sensors may comprise a vibration sensor, a pressure sensor, a temperature sensor, a flow rate sensor, or any combination thereof.

The one or more sensors may comprise a refractometer to measure a weight percent of a component of the liquid coolant, such as a glycol, a corrosion inhibitor, or any other additive disclosed herein.

The heat exchanger may comprise a pump and the controller may be configured to predict pump failure.

The controller may be configured to monitor air-side temperature, dewpoint, and/or operational modifications of the high-performance computing system with the one or more additional sensors. The controller may be configured to perform real-time monitoring of the heat exchanger with the one or more additional sensors. The controller may be configured to predict fluid life of the liquid coolant with the one or more sensors.

The controller may be configured to determine current heat load requirements of the high-performance computing system and modify flow rate of the heat exchanger and/or the liquid coolant in response to a determination of the current heat load requirements.

The controller may be configured to transmit the sensor data to a remote device and/or store the sensor data. The controller may be configured to receive a control input from a user interface device of the controller and store the control input with reference to the sensor data. The controller may be configured to compare the sensor data to one or more predetermined sensor data values and optionally activate an alarm in response to comparison of the sensor data to the one or more predetermined sensor data values. The controller may be configured to add an additive to the secondary coolant loop in response to comparison of the sensor data to the one or more predetermined sensor data values. In some embodiments, the one or more predetermined sensor data values comprise a minimum glycol weight percentage and the additive comprises a glycol.

The additive may comprise a dispersant, a surfactant, a heat transfer additive, an inhibitor, a biocide, a scouring agent, a glycol, water, or any combination thereof.

The controller may be configured to discharge at least a portion of the liquid coolant from the secondary coolant loop coupled to the liquid cooling conduit based on the sensor data and add additional liquid coolant to the secondary coolant loop in response to the discharge of the portion of the liquid coolant.

The controller may be configured to evaluate a property of the liquid coolant with an artificial intelligence model to determine health of the liquid coolant, wherein the artificial intelligence model is locally executed by the controller or remotely hosted by a remote computing device.

The system may further comprise a cooling distribution unit and the cooling distribution unit includes the heat exchanger.

The present disclosure also provides a device for computing device cooling liquid monitoring. The device comprises a frame adapted to be received in a high-performance computing blade enclosure wherein the frame comprises a pair of opposing side surfaces spaced apart by a predetermined distance. The system also includes a liquid cooling conduit, one or more liquid connectors, such as a pair of liquid connectors, coupled to the frame and fluidly coupled to the liquid cooling conduit, and one or more sensors fluidly coupled to the liquid cooling conduit. The one or more sensors are configured to generate sensor data indicative of one or more properties of a liquid coolant within the liquid cooling conduit. The liquid connector is configured to be removably coupled to a secondary coolant loop of the high-performance computing blade enclosure when the coolant blade is received in the high-performance computing blade enclosure.

The liquid cooling conduit may be mounted to the frame. The liquid connector may be mounted to a panel of the frame. The frame may comprise a first panel that separates the side surfaces and the liquid connector may be mounted to the first panel.

The liquid coolant may comprise water and/or a glycol. The liquid coolant may comprise a corrosion inhibitor, a scale inhibitor, a buffer, a dispersant, a biocide, a scouring agent, a viscosity modifier, a heat transfer additive, a surfactant, a glycol, water, or any combination thereof.

The one or more sensors may comprise a refractometer to measure weight percent of a component (such as an additive disclosed herein) in the liquid coolant.

The one or more sensors may comprise a conductivity sensor, a turbidity sensor, a pH sensor, a temperature sensor, a flow rate sensor, a fluorometer, a color sensor, a dissolved oxygen sensor, a pressure sensor, a differential pressure sensor, a vibration sensor, an IR light sensor, an alkalinity sensor, an entrained air sensor, a particle size sensor, a sensor for measuring glycol wt. %, or any combination thereof. In some embodiments, the one or more sensors comprise a microbiology sensor, an oxidation-reduction potential sensor, or a device for measuring organic and/or inorganic fouling. The device may comprise a leak detection sensor coupled to the frame.

The liquid connector may comprise an inlet connector and an outlet connector and when the coolant blade is received in the high-performance computing blade enclosure, the inlet connector is fluidly coupled to a supply manifold of the high-performance computing blade enclosure and the outlet connector is fluidly coupled to a return manifold of the high-performance computing blade enclosure.

The secondary cooling loop of the high-performance computing blade enclosure may be coupled to a heat exchanger. The heat exchanger may be coupled to a primary cooling loop. In some embodiments, the cooling distribution unit comprises the heat exchanger.

Certain aspects of the present disclosure are also directed to a system for computing device cooling liquid monitoring. The system comprises a coolant blade adapted to be received in a high-performance computing blade enclosure. The coolant blade comprises a pair of opposing side surfaces separated by a predetermined distance, a liquid cooling conduit, one or more liquid connectors, such as a pair of liquid connectors, fluidly coupled to the liquid cooling conduit, one or more sensors fluidly coupled to the liquid cooling conduit, and a controller coupled to the sensors of the coolant blade. The liquid connector is configured to be removably coupled to a secondary coolant loop of the high-performance computing blade enclosure when the coolant blade is received in the high-performance computing blade enclosure. The controller is configured to receive sensor data indicative of one or more properties of a liquid coolant within the liquid cooling conduit from the one or more sensors.

The liquid cooling conduit may be mounted to the coolant blade. The liquid connector may be mounted to a panel of the coolant blade. The coolant blade may further comprise a first panel that separates the side surfaces and the liquid connector may be mounted to the first panel.

The liquid coolant may comprise water and/or a glycol. The liquid coolant may comprise an additive selected from the group consisting of a corrosion inhibitor, a scale inhibitor, a buffer, a dispersant, a biocide, a scouring agent, a viscosity modifier, a heat transfer additive, a surfactant, a glycol, water, and any combination thereof.

The one or more sensors may comprise a refractometer to measure the weight percent of a component in the liquid coolant, such as a glycol, a corrosion inhibitor, or any additive disclosed herein.

The one or more sensors may comprise a conductivity sensor, a turbidity sensor, a pH sensor, a temperature sensor, a flow rate sensor, a fluorometer, a color sensor, a dissolved oxygen sensor, a pressure sensor, a differential pressure sensor, a vibration sensor, an IR light sensor, an alkalinity sensor, an entrained air sensor, a sensor for measuring glycol wt. %, or any combination thereof. In some embodiments, the one or more sensors comprise a microbiology sensor, an oxidation-reduction potential sensor, or a device for measuring organic and/or inorganic fouling.

The coolant blade may further comprise a leak detection sensor.

The liquid connector may comprise an inlet connector and an outlet connector and when the coolant blade is received in the high-performance computing blade enclosure, the inlet connector is fluidly coupled to a supply manifold of the high-performance computing blade enclosure and the outlet connector is fluidly coupled to a return manifold of the high-performance computing blade enclosure.

The secondary cooling loop of the high-performance computing blade enclosure may be coupled to a heat exchanger. The heat exchanger may be coupled to a primary cooling loop. A cooling distribution unit may comprise the heat exchanger.

In some embodiments, the controller is configured to transmit the sensor data to a remote device and/or store the sensor data. The controller may be configured to receive a control input from a user interface device of the controller and to store the control input with reference to the sensor data. The controller may be configured to detect a blade change based on the control input or based on the sensor data.

For example, a change in the weight percentage of glycol in the coolant could indicate a blade change has occurred. Similarly, a change in conductivity and/or detection of particles in the medium could be indicators of a blade change. Likewise, a blade change could be indicated by step changes in conductivity, weight percent glycol, and/or detection of particles.

The controller may be configured to add additional liquid coolant to the secondary coolant loop or discharge at least a portion of the liquid coolant from the secondary coolant loop in response to detection of the blade change. The controller may be configured to compare the sensor data to one or more predetermined sensor data values and optionally activate an alarm in response to comparison of the sensor data to the one or more predetermined sensor data values. The controller may be configured to add an additive to the secondary coolant loop in response to comparison of the sensor data to the one or more predetermined sensor data values. In some embodiments, the one or more predetermined sensor data values comprise a minimum glycol weight percentage and the additive comprises a glycol.

The additive may comprise a dispersant, a surfactant, a heat transfer additive, an inhibitor, a biocide, a scouring agent, a glycol, water, or any combination thereof.

The controller may be configured to cause discharge of at least a portion of the coolant from a secondary coolant loop coupled to the liquid cooling conduit based on the sensor data and cause addition of additional liquid coolant to the secondary coolant loop in response to the discharge of the portion of the coolant.

The present disclosure also provides a method for computing device cooling liquid monitoring. The method comprises generating, by one or more sensors, sensor data indicative of one or more properties of a liquid coolant within a liquid cooling conduit of a coolant blade, wherein the coolant blade is adapted to be received in a high-performance computing blade enclosure and the one or more sensors are fluidly coupled to the liquid cooling conduit. The method also comprises receiving, by a controller, the sensor data indicative of the one or more properties from the one or more sensors. The liquid coolant may comprise water and/or a glycol.

Generating the sensor data may comprise measuring a weight percent of a component of the liquid coolant with a refractometer. Generating the sensor data may comprise measuring conductivity, turbidity, pH, temperature, and/or flow rate of the liquid coolant. Generating the sensor data may comprise measuring microbiology and/or oxidation-reduction potential of the liquid coolant.

The method may further comprise transmitting, by the controller, the sensor data to a remote device. The method may further comprise storing, by the controller, the sensor data. The method may further comprise receiving, by the controller, a control input from a user interface device of the controller and storing, by the controller, the control input with reference to the sensor data.

The method may further comprise detecting, by the controller, a blade change based on the control input or based on the sensor data. The method may further comprise causing, by the controller, addition of more liquid coolant to the secondary coolant loop or discharge of at least a portion of the liquid coolant from the secondary coolant loop in response to detecting the blade change.

The method may further comprise comparing, by the controller, the sensor data to one or more predetermined sensor data values and optionally activating, by the controller, an alarm in response comparing the sensor data to the one or more predetermined sensor data values.

The method may further comprise causing, by the controller, addition of an additive to the liquid cooling conduit in response to comparing the sensor data to the one or more predetermined sensor data values.

The one or more predetermined sensor data values may comprise a minimum glycol weight percentage and the additive may comprise a glycol.

The additive may comprise a dispersant, a surfactant, a heat transfer additive, an inhibitor, a biocide, a scouring agent, a glycol, water, or any combination thereof.

The method may further comprise causing, by the controller, discharge of at least a portion of the liquid coolant from a secondary coolant loop coupled to the liquid cooling conduit based on the sensor data and causing, by the controller, addition of liquid coolant to the secondary coolant loop in response to causing the discharge of the portion of the coolant.

The present disclosure also provides a method of monitoring and controlling a property of a medium. The method comprises:
(a) providing a monitoring and controlling unit comprising a controller and a sensor in communication with the controller, wherein the sensor is operable to measure a property of the medium selected from the group consisting of weight % glycol, pH, and conductivity;
(b) providing a chemical injection pump, which is in communication with the controller;
(c) entering an acceptable range for the property into the controller;
(d) providing a delivery conduit having a first end in fluid communication with the medium and a second end in fluid communication with an inlet of the monitoring and controlling unit;
(e) delivering a sample of the medium through the delivery conduit to the monitoring and controlling unit;
(f) measuring the property in the sample with the sensor;
(g) determining if the measured property is within the acceptable range entered into the controller in step (c);
(h) carrying out a corrective action if the measured property is outside of the acceptable range entered into the controller in step (c); and
(i) optionally repeating steps (a) to (h) to determine if the property has been brought within the acceptable range entered in step (c).

The corrective action may comprise adding an additive into the medium, opening a valve, closing a valve, adding a glycol to the medium, adding an acid to the medium, adding a base to the medium, adding water to the medium, or any combination thereof.

Certain aspects of the present disclosure relate to a computing device comprising a processor and a memory having stored therein a plurality of instructions that when executed by the processor cause the computing device to perform any method disclosed herein.

The present disclosure also provides one or more machine readable storage media comprising a plurality of instructions stored thereon that in response to being executed result in a computing device performing any method disclosed herein.

Certain aspects of the present disclosure relate to a computing device comprising means for performing any method disclosed herein.

The foregoing has outlined rather broadly the features and technical advantages of the present disclosure in order that the detailed description that follows may be better understood. Additional features and advantages of the disclosure will be described hereinafter that form the subject of the claims of this application. It should be appreciated by those skilled in the art that the conception and the specific embodiments disclosed may be readily utilized as a basis for modifying or designing other embodiments for carrying out the same purposes of the present disclosure. It should also be realized by those skilled in the art that such equivalent embodiments do not depart from the spirit and scope of the disclosure as set forth in the appended claims.

### BRIEF DESCRIPTION OF THE SEVERAL VIEWS OF THE DRAWINGS

A detailed description of the invention is hereafter described with specific reference being made to the drawings in which:

FIG. 1 shows a simplified block diagram of a system for high-performance computing with liquid cooling;

FIG. 2 shows a simplified block diagram of at least one embodiment of a liquid monitoring system for a high-performance computing system with liquid cooling;

FIG. 3 shows a simplified block diagram of at least one embodiment of another liquid monitoring system for a high-performance computing system with liquid cooling;

FIG. 4 shows a diagram of at least one embodiment of a coolant blade of the liquid monitoring system of FIG. 3;

FIG. 5 shows a simplified flow diagram of at least one embodiment of a method for liquid cooling system monitoring that may be executed by a controller of FIGS. 2-4; and

FIG. 6 shows a simplified block diagram of an illustrative embodiment of a liquid monitoring system for a high-performance computing system with liquid cooling.

### DETAILED DESCRIPTION

Various embodiments are described below with reference to the drawings in which like elements generally are referred to by like numerals. The relationship and functioning of the various elements of the embodiments may better be understood by reference to the following detailed description. However, embodiments are not limited to those illustrated in the drawings. It should be understood that the drawings are not necessarily to scale, and in certain instances details may have been omitted that are not necessary for an understanding of embodiments disclosed herein, such as conventional fabrication and assembly.

The disclosed embodiments may be implemented, in some cases, in hardware, firmware, software, or any combination thereof. The disclosed embodiments may also be implemented as instructions carried by or stored on one or more transitory or non-transitory machine-readable (e.g., computer-readable) storage media, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

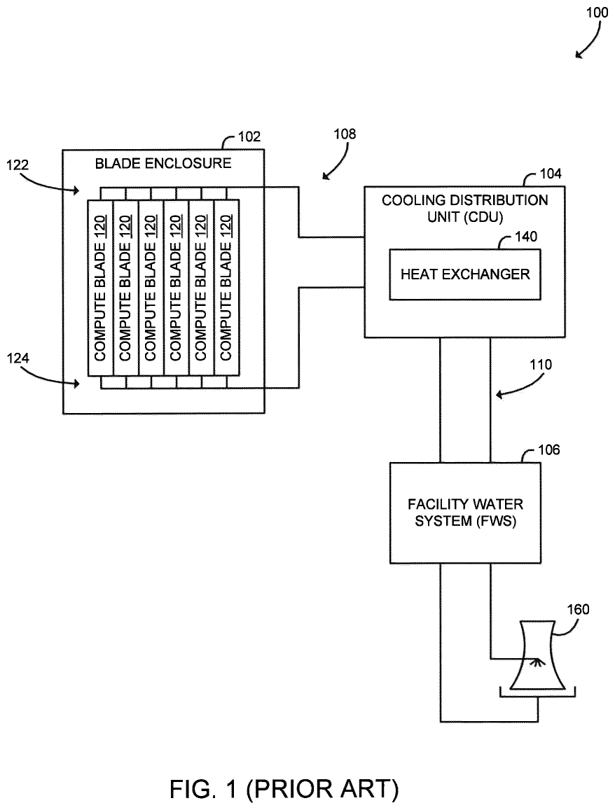

Referring now to FIG. 1, a typical computing system 100 with liquid cooling includes a computing blade enclosure 102 that includes multiple compute blades 120. Although illustrated as including a blade enclosure 102, it should be understood that the system 100 may include any appropriate chassis, rack, frame, or other enclosure configured to support multiple compute blades 120 or other high-density computing devices. Additionally, although illustrated as including a single blade enclosure 102, it should be understood that the system 100 may include multiple blade enclosures 102 which may be arranged in rows or otherwise combined to form a high-performance computing (HPC) system, supercomputer, computing cluster, data center, server farm, or other computing system that includes liquid-cooled computing units.

Each of the compute blades 120 may be embodied as individual computing devices, servers, nodes, or other heat-generating computing devices. The blade enclosure 102 includes a number of bays or slots of standardized dimensions, and each compute blade 120 may have a standard size and/or other standardized physical characteristics such that each compute blade 120 may be received in a corresponding bay or slot of the blade enclosure 102. In some embodiments, the bays or slots may have a height or other dimension that is smaller than a typical “1U” rack height, allowing the blade enclosure 102 to support high compute density.

The blade enclosure 102 further includes a supply manifold 122 and a return manifold 124, which are configured to distribute coolant (e.g., cooling liquid, such as water, a glycol, or a combination thereof) to the compute blades 120 and to collect the coolant from the compute blades 120. The blade enclosure 102 may further include power, networking, and/or other connections or components configured to support operations of the compute blades 120.

As shown, the blade enclosure 102 is coupled to a one or more cooling distribution unit (CDU) 104 via a technology cooling system (TCS) 108, also called a secondary coolant loop 108. In any embodiment disclosed herein, CDU 104 may be replaced with a heat exchanger. It is to be understood TCS 108 may be embodied as one or more pipes or other liquid conduits capable of transferring coolant from the CDU 104 to the blade enclosure 102 and back. The CDU 104 includes a heat exchanger 140 configured to extract heat from the TCS 108. The CDU 104 may also include one or more additional components configured to support circulating coolant to the blade enclosure 102, such as pumps, thermostats, filters, and/or other components.

The CDU 104 is coupled to a facility water system (FWS) 106 via a primary loop 110. The primary loop 110 may be embodied as one or more pipes or other liquid conduits capable of transferring facility water or other coolant between the FWS 106 and the CDU 104. The FWS 106 is illustratively coupled to a cooling tower 160, which rejects heat from the FWS 106 to the environment. Additionally, the FWS 106 may include and/or be coupled to one or more additional components to support rejecting heat, such as one or more chillers, additional liquid loops, thermostats, condensers, and/or other components.

In use, the CDU 104 supplies cool coolant to the blade enclosure 102 via the TCS 108. The coolant may be maintained at an appropriate temperature, such as a temperature above a dew point at the location of the blade enclosure 102 (e.g., about 30° F., about 35° F., about 40° F., about 45° F., etc.) in order to avoid condensation or other issues. The coolant is distributed through the supply manifold 122 to the compute blades 120. In each of the compute blades 120, the coolant flows through one or more cold plates, water blocks, or other cooling components coupled to processors, graphical processing units (GPUs), application specific integrated circuits (ASICs), or other heat-generating components of the compute blades 120. Warm coolant from the compute blades 120 is collected by the return manifold 124 and returned to the CDU 104. Heat from the warm coolant is transferred to the FWS 106 using the heat exchanger 140, and then this heat is rejected to the environment using the cooling tower 160.

Although illustrated as including a single blade enclosure 102 and CDU 104, it should be understood that in some embodiments, the system 100 may include multiple blade enclosures 102 and/or CDUs 104 (and/or heat exchangers). Additionally, in some embodiments, the CDU 104 may use a different technique to cool the coolant in the TCS 108. For example, in some embodiments, the CDU 104 may be air-cooled and may not require a connection to the facility primary loop 110.

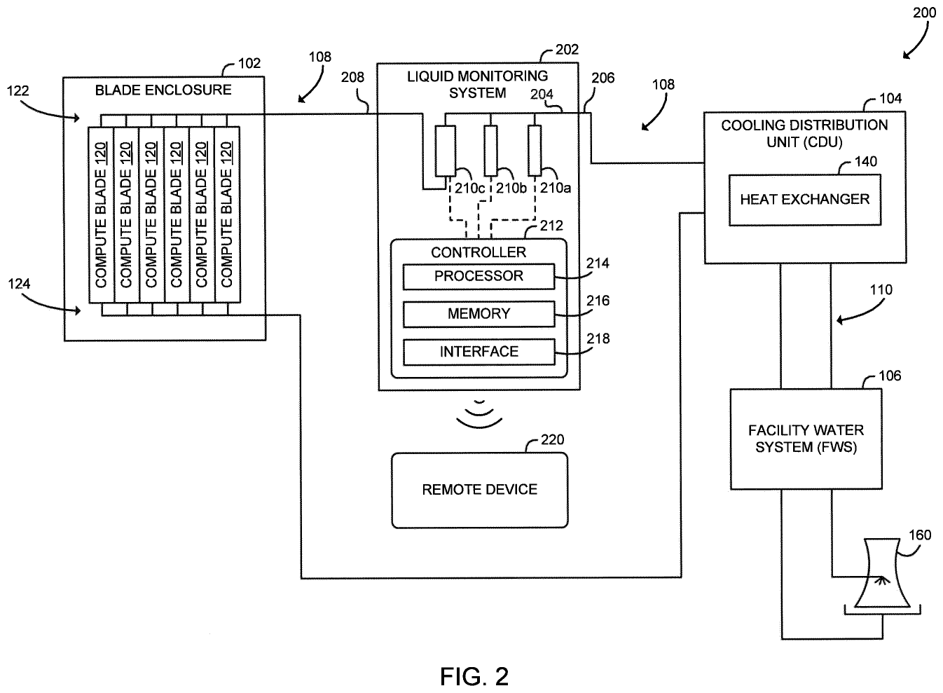

Referring now to FIG. 2, a system 200 for liquid coolant monitoring for a liquid cooled computing system includes a blade enclosure 102, CDU 104, and FWS 106 similar to those described above in connection with FIG. 1. Additionally, and as shown in FIG. 2, the system 200 includes a liquid monitoring system 202 that is coupled to the secondary loop 108 between the CDU 104 and the blade enclosure 102. The liquid monitoring system 202 includes an internal liquid conduit 204 that extends between an inlet 206 and an outlet 208. As shown, the inlet 206 is coupled to the CDU 104 via the TCS 108, and the outlet 208 is coupled to the inlet manifold 122 of the blade enclosure 102 via the TCS 108. Thus, coolant provided by the CDU 104 passes through the conduit 204 of the liquid monitoring system 202 before being provided to the blade enclosure 102. It should be understood that in other embodiments, the liquid monitoring system 202 may be coupled to the system 200 in one or more other configurations. For example, in an embodiment, the liquid monitoring system 202 may be coupled to the return leg of the TCS 108 (i.e., coupled between the return manifold 124 of the blade enclosure 102 and the CDU 104. As another example, in an embodiment with multiple blade enclosures 102, the liquid monitoring system 202 may be coupled between blade enclosures 102.

The liquid monitoring system 202 further includes one or more sensors 210 that are each coupled to the conduit 204. Illustratively, the liquid monitoring system 202 includes three sensors 210a, 210b, 210c, however, in other embodiments, the system 202 may include a different number of sensors 210, such as one, two, four, five, six, seven, eight, nine, ten, or more. Each of the sensors 210 may be embodied as any electronic sensor capable of monitoring or otherwise measuring one or more properties of the coolant, such as turbidity, pH, percent glycol (e.g., wt. % propylene glycol in the liquid coolant), conductivity, fluorescence, color, dissolved oxygen content, flow rate, pressure, IR light, alkalinity, entrained air, or other properties. Those measured properties may be indicative of coolant health. For example, the sensors 210 may include a sensor for online-refractometry to measure percentage propylene glycol. As another example, the sensors 210 may include a filter fitted with pressure sensors for measuring differential pressure across the filter. As another example, the sensors 210 may measure absorbance or fluorescence to monitor pH via an indicator. Further, the sensors 210 may measure color to determine coolant health, for example, by monitoring the inherent color of the glycol, color of a dye added as an inert additive, or measuring UV absorbance as a surrogate for total organic carbon (TOC). As an additional example, the sensors 210 may measure dissolved oxygen in the coolant, which may be indicative of glycol degradation. As another example, the sensors 210 may measure pressure and vibration, for example, at a recirculation pump outlet. In some embodiments, the liquid monitoring system 202 may include additional sensors that may not be directly fluidly coupled to the conduit 204, such as leak sensors, fluid reservoir volume sensors, or other sensors that may be coupled to, for example, other conduits in the system, such as TCS 108, a conduit of manifold 122, a conduit of manifold 124, etc.

In some embodiments, the liquid monitoring system 202 may be used to monitor treated water systems in addition to, or alternatively to, liquid cooling systems. In those embodiments, the liquid monitoring system 202 may include the sensors 210 described above (without the refractometer in some embodiments) along with additional sensors for microbiology sensing, oxidation-reduction potential (ORP), or other sensors for monitoring properties and/or concentrations of components, such as inhibitor residuals. In some embodiments, the liquid monitoring system 202 may include sensors 210 for measuring organic and/or inorganic deposits or other fouling.

Each of the sensors 210 is communicatively coupled to a controller 212. The illustrative controller 212 may be embodied as any programmable logic controller, microcontroller, microprocessor, or other device capable of performing the functions described herein. To do so, the controller 212 may include a number of electronic components commonly associated with units utilized in the control of electronic and electromechanical systems. For example, the controller 212 may include, amongst other components customarily included in such devices, a processor 214 and a memory device 216. The processor 214 may be any type of device capable of executing software or firmware, such as a microcontroller, microprocessor, digital signal processor, or the like. The memory device 216 may be embodied as one or more volatile and/or non-volatile memory device. The memory device 216 is provided to store, amongst other things, instructions in the form of, for example, a software routine (or routines) which, when executed by the processor 214, allows the controller 212 to monitor sensor data from the sensors 210 as described herein. The controller 212 also includes an interface circuit 218, which may be embodied as any analog and/or digital electrical circuit(s), component, or collection of components capable of performing the functions described herein. The interface circuit 218 converts output signals (e.g., from the sensors 210) into signals which are suitable for presentation to an input of the processor 212. In particular, in some embodiments, the interface circuit 218, by an analog-to-digital (A/D) converter, or the like, converts analog signals into digital signals for use by the processor 214. Similarly, the interface circuit 218 may convert signals from the processor 214 into output signals which are suitable for presentation to the electrically-controlled components associated with system 202 (e.g., one or more pumps or other components). In particular, the interface circuit 218, by use of a variable-frequency signal generator, digital-to-analog (D/A) converter, or the like, may convert digital signals generated by the processor 214 into analog signals for use by the electrically-controlled components associated with the system 202. It is contemplated that, in some embodiments, the interface circuit 218 (or portions thereof) may be integrated into the processor 214.

The controller 212 may be in wireless communication with a remote computing device 220. The remote computing device 220 may be embodied as any controller, computer, server device, or other device capable of performing the functions described herein. In some embodiments, the remote device 220 may be embodied as a gateway device or other device configured to receive data from the controller 212 and forward that data to another remote device 220, such as a digital platform server. For example, in some embodiments, the remote device 220 may be embodied as a Nalco Global Gateway. Accordingly, the remote computing device 220 may include components typically found in a server computer, such as a process, a memory, and various interface circuits. The above description of similar components of the controller 212 is applicable to similar components of the remote device 220 and for clarity is not repeated herein.

The illustrative liquid monitoring system 202 may be physically installed on a stand, a sled, a skid, a plate, or other physical structure to support components of the liquid monitoring system 202 and to allow for physical installation of the liquid monitoring system 202 at the computing system 100. For example, in some embodiments, the liquid monitoring system 202 may be mounted to a freestanding stand that may be positioned near the CDU 104 and the blade enclosure 102. The secondary loop 108 may be thus routed from the CDU 104 to the blade enclosure 102 through the liquid monitoring system 202. As another example, in some embodiments the liquid monitoring system 202 may be mounted to a sled, a skid, a plate, or other structure that may be physically attached to the blade enclosure 102, the CDU 104, or another structure. For example, in some embodiments, the liquid monitoring system 202 may be attached to a wall or other structure near the blade enclosure 102 and the CDU 104. As another example, in some embodiments the liquid monitoring system 202 may be attached to a side panel of the blade enclosure 102. This arrangement may allow for access to the compute blades 120 while also providing access to the liquid monitoring system 202, for maintenance or other tasks. As yet another example, the liquid monitoring system 202 may be attached to a front panel of the CDU 104, which allows for access to the liquid monitoring system 202 for maintenance or other tasks.

Thus, system 200 allows for automated, real-time or near real-time monitoring of coolant properties for liquid cooled computing systems. Compared to previous liquid cooled computing systems, the system 200 may allow for monitoring additional coolant properties continually, with improved accuracy or otherwise improved monitoring quality. Such monitoring may allow for improved coolant quality (e.g., ensuring properties remain within accepted ranges or thresholds), which in turn may improve cooling performance and/or computing performance of the system 200.

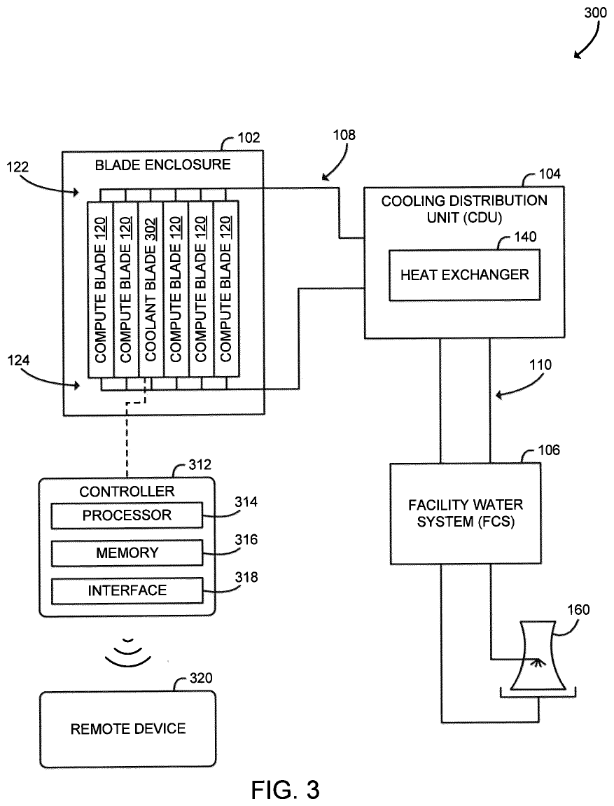

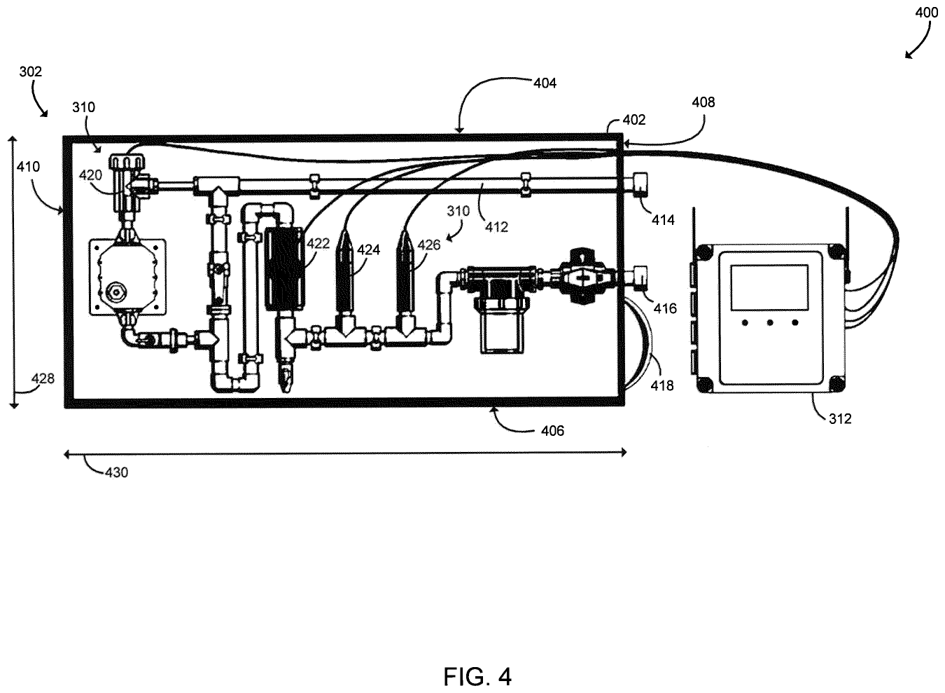

Referring now to FIG. 3, a system 300 for liquid cooling monitoring for a liquid cooled computing system includes a blade enclosure 102, CDU 104, and FWS 106 similar to those described above in connection with FIGS. 1 and 2. Additionally, and as shown in FIG. 3, the system 300 includes a coolant blade 302 mounted to the blade enclosure 102. As described further below, the coolant blade 302 includes sensors 310 (illustratively shown in FIG. 4) and a cooling liquid conduit similar to the liquid monitoring system 202 shown in FIG. 2. Additionally, the coolant blade 302 is adapted to be received in the same bays or slots of the blade enclosure 102 as the compute blades 120. In particular, the coolant blade is coupled to the supply manifold 122 and the return manifold 124. As coolant circulates through the secondary loop 108, a portion of the coolant passes through the coolant blade 302, which uses sensors to monitor one or more properties of the coolant, similar to the liquid monitoring system 202 of FIG. 2. The secondary loop 108 has a relatively small volume of coolant, and thus over time, all or substantially all of the coolant within the secondary loop 108 passes through the coolant blade 302 for monitoring.

As shown in FIG. 3, the coolant blade 302 is communicatively coupled to a controller 312, which includes a processor 314, a memory 316, and an interface 318. The illustrative controller 312 may be the same as or similar to the controller 212 of FIG. 2. As shown, the controller 312 may also be in communication with a remote computing device 320, which may be the same as or similar to the remote computing device 220 of FIG. 2. Accordingly, the description of the controller 212 and its components is also applicable to the controller 312 and its components, and the description of the remote computing device 220 is also applicable to the remote computing device 320. To improve clarity of this disclosure, those descriptions are not repeated herein.

Thus, the system 300, including the coolant blade 302, allows for automated, real-time or near real-time monitoring of coolant properties for liquid cooled computing system. Similar to the system 200, the system 300 allows for monitoring additional coolant properties continually, with improved accuracy and/or otherwise improved monitoring quality. Such monitoring may allow for improved troubleshooting and other maintenance of the coolant system, thus improving coolant quality (e.g., by performing early maintenance to ensure properties remain within accepted ranges or thresholds). Improved maintenance, troubleshooting, and/or coolant quality may thus improve cooling performance and/or computing performance of the system 300. Additionally, by using a coolant blade 302 that is interchangeable with a compute blade 120, the system 300 may provide improved coolant monitoring without requiring modifications to existing liquid cooling systems (e.g., without requiring connection to the secondary loop 108 outside of the blade enclosure 302). Thus, the system 300 may reduce costs or otherwise improve efficiency associated with liquid coolant monitoring. Further, the coolant blade 302 may be incorporated into the system 300 without requiring additional space for liquid coolant monitoring, which is desirable for many high-performance computing systems in which space is at a premium.

Referring now to FIG. 4, diagram 400 illustrates one potential embodiment of a coolant blade 302 of the system 300. The illustrative coolant blade 302 includes a chassis 402 that supports and encloses components of the coolant blade 302. The chassis 402 illustratively includes a pair of opposing side panels 404, 406, a front panel 408, and a rear panel 410. The chassis 402 may also include a top panel and a bottom panel, which are not specifically shown in FIG. 4.

The illustrative coolant blade 302 includes a liquid conduit 412 or other passage that extends throughout the interior of the chassis 402. The liquid conduit 412 may include one or more pipes, valves, and other components capable of containing pressurized coolant. The coolant blade 302 further includes an inlet connector 414 and an outlet connector 416 that are fluidly coupled to the liquid conduit 412. The connectors 414, 416 are configured to connect to the secondary loop 108 of the system 300, for example by connecting to the supply manifold 122 and the return manifold 124 or other liquid coolant handling components of the blade enclosure 102. The connectors 414, 416 are illustratively quick connect connectors; however, the connectors 414, 416 may be embodied as any liquid connector compatible with the blade enclosure 102.

The chassis 404 may further include a handle 418 extending outward from the front panel 408. The handle 418 may be used to facilitate inserting the chassis 402 into a bay or slot of the blade enclosure 102. Illustratively, the connectors 414, 416 also extend outwardly from the front panel 408 of the chassis 402, so that the connectors 414, 416 are accessible when the chassis 402 is inserted in the blade enclosure 102. In other embodiments, the connectors 414, 416 may extend from the rear panel 410 or be otherwise arranged relative to the chassis 402 to connect to the blade enclosure 102 when the chassis 402 is inserted in the blade enclosure 102. Similarly, the chassis 402 may include one or more locking levers, attachment devices, or other mechanical features to support installation in the blade enclosure 102.

As shown, the illustrative coolant blade 302 includes multiple sensors 310 that are fluidly coupled to the liquid conduit 412 and positioned in an interior of the chassis 402. Illustratively, the diagram 400 includes four sensors 420, 422, 424, 426 fluidly coupled to the liquid conduit 412. Similar to the sensors 210 of the liquid monitoring system 202 of FIG. 2, each of the sensors 310 may be embodied as any electronic sensor capable of monitoring or otherwise measuring one or more properties of the coolant, such as turbidity, pH, percentage glycol, conductivity, temperature, flow rate, IR light, alkalinity, entrained air, or other properties. Those measured properties may be indicative of coolant health. For example, the sensors 310 may include a sensor for online-refractometry to measure percentage propylene glycol. As another example, the sensors may include a filter fitted with pressure sensors for measuring differential pressure across the filter as an additional data point for fluid health and particulate. Further, the sensors may measure absorbance or fluorescence to monitor pH via an indicator. In some embodiments, the sensors may include additional sensors for microbiology sensing, oxidation-reduction potential (ORP), or other sensors for monitoring for inhibitor residuals.

The sensors 420, 422, 424, 426 are illustratively communicatively coupled to the controller 312. As described further below, and similar to the controller 212, the controller 312 is configured to receive sensor data from the sensors, process the sensor data, and in some embodiments to transmit the sensor data to one or more remote devices 320. As shown, in the illustrative embodiment, the controller 312 is a component separate from the chassis 402 and connected to the sensors 420, 422, 424, 426. In this illustrative embodiment, the controller 312 may be attached or otherwise positioned in an accessible location. For example, the controller 312 may be attached to an outside surface of the blade enclosure 102 or another location that is accessible by a maintenance technician or other user. Additionally, although illustrated as using wired connections to the sensors 310, it should be understood that in some embodiments the controller 312 may be connected to the sensors 310 wirelessly.

In some embodiments, some or all components of the controller 312 may be included inside or otherwise incorporated with the chassis 402 of the coolant blade 302. For example, in an embodiment the controller 312 may be positioned inside the chassis 402 and connected to the sensors 420, 422, 424, 426 by wires. In some embodiments, one or more screens, buttons, or other user interface devices of the controller 312 may be user-accessible, for example by being positioned on (or otherwise accessible through) the front panel 408 of the chassis 402.

As shown, the chassis 402 includes a width 428 and a depth 430. The chassis 402 may also include a height (not shown). Those dimensions may be similar to standardized dimensions of one or more compute blades 120 that are compatible with the blade enclosure 102. For example, in some embodiments, the chassis 402 may have width 428, depth 430, and height equal to a full-height blade or a double-height blade used with a blade enclosure 102. As another example, in some embodiments the chassis 402 may have a width 428 equal to a standard rack width (e.g., about 10 inches to about 30 inches, such as about 15, about 16, about 17, about 18, about 19, or about 20 inches, or a width less than about 10 inches or greater than about 30 inches).

In some embodiments, the chassis 402 may include additional features providing access to the secondary loop 108 for maintenance or other purposes. For example, in an embodiment, the chassis 402 may include an additional port positioned on the front panel 408 or other accessible location of the chassis 402 that is fluidly coupled to the liquid conduit 412, and thus to the secondary loop 108. Continuing that example, pressurized cartridges, bottles, or other containers of chemicals, such as a glycol, may be attached to the liquid conduit 412 using this port in order to add those chemicals to the secondary loop 108. Such additions may be based on measurements of the coolant generated by the coolant blade 302. Accordingly, the coolant blade 302 may allow for addition of chemicals to the secondary loop 108 without interrupting coolant flow from the CDU 104 and with reduced risk of contamination compared to typical systems.

In some embodiments, the chassis 402 may include additional sensors or other data sources for the controller 312. For example, in an embodiment, the chassis may include one or more leak detection sensors. Those sensors may not be fluidly coupled to the liquid conduit 412.

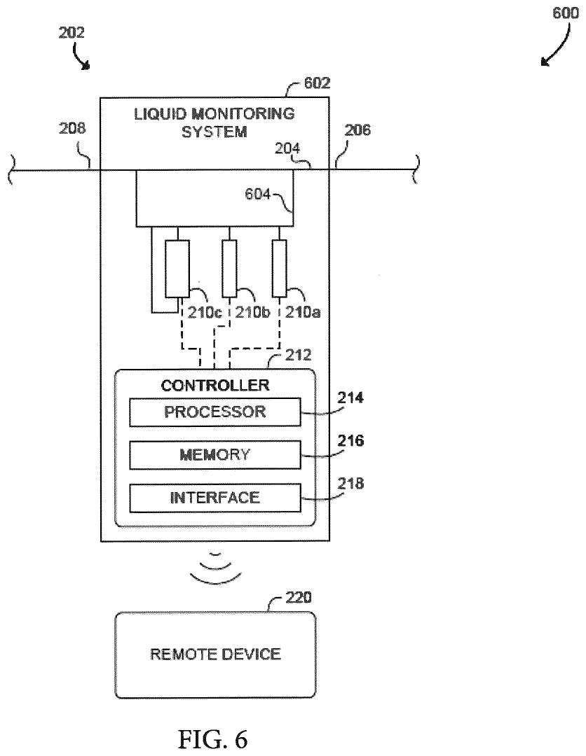

Referring now to FIG. 6, diagram 600 illustrates another potential embodiment of a liquid monitoring system 602 that may be used with the system 200 of FIG. 2. As shown, the illustrative system 602 includes many of the same components of the liquid monitoring system 202 shown in FIG. 2, the description of which is applicable to the corresponding components of the liquid monitoring system 602 and is not repeated herein so as not to obscure the present disclosure. Thus, the liquid monitoring system 602 may be used with the system 200 in place of and/or together with the liquid monitoring system 202, for example, by coupling the inlet 206 to the CDU 104 via the TCS 108, and coupling the outlet 208 to the inlet manifold 122 of the blade enclosure 102 via the TCS 108.

As shown, the liquid monitoring system 602 includes an internal liquid conduit 204 that extends between the inlet 206 and the outlet 208. The liquid monitoring system 602 further includes a side channel 604 coupled to the liquid conduit 204. The sensors 210 are coupled to the side channel 604. Accordingly, at least a part of the coolant received at the inlet 206 passes through the conduit 204 and then the side channel 604, wherein the coolant may be measured by one or more of the sensors 210. The TCS 108 has a relatively small volume of coolant, and thus over time, all or substantially all of the coolant within the TCS 108 passes through the side channel 604 for monitoring.

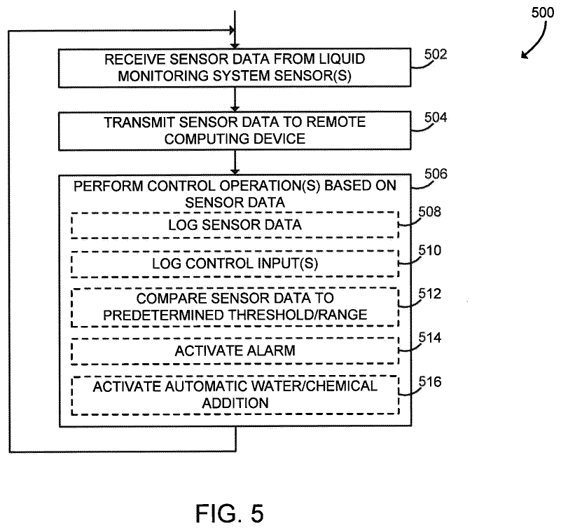

Referring now to FIG. 5, in use, a controller 212 or a controller 312 may execute a method 500 for monitoring and/or controlling the liquid monitoring system 202, 602, or a coolant blade 302. The method 500 begins in block 502, in which the controller 212, 312 receives sensor data from one or more sensors 210, 310 of the liquid monitoring system 202/602 or coolant blade 302, respectively. In block 504, the controller 212, 312 transmits the sensor data to a remote computing device 220, 320. The remote computing device may be, for example, a Nalco Global Gateway, a digital platform server device, or other device.

In block 506, the controller 212, 312 may perform one or more control operations or other automation operations based on the sensor data. In some embodiments, in block 508, the controller 212, 312 may log the sensor data for later review and/or analysis. In some embodiments, the sensor data may be logged by the remote device 220, 320 in addition to or alternatively to the controller 212, 312. In some embodiments, in block 510 the controller 212, 312 may log one or more control inputs made by a user to the controller 212, 312. For example, in certain embodiments, a technician may press a button, select a graphical user interface element, or otherwise activate a control input of the controller 212, 312 whenever a compute blade 120 or other component of the system 200, 300 is added, removed, swapped, or otherwise changed. The controller 212, 312 may store a timestamp associated with the control input. Those logged control inputs associated with compute blade 120 change events may be compared to logged sensor data, for example to identify any changes to coolant properties caused by the compute blade 120 change event. Logging sensor data and/or user input events may provide for insight into physical changes to the computing system that is not actionable with typical systems.

In some embodiments, in block 512, the controller 212, 312 may compare sensor data to one or more predetermined thresholds and/or predetermined ranges. For example, the controller 212, 312 may compare a measured percentage glycol (e.g., propylene glycol) in the coolant to a predetermined acceptable range of glycol percentages. In some embodiments, in block 514 the controller 212, 312 may activate an alarm based on sensor data, for example, in response to comparing the sensor data to the predetermined threshold or range. The alarm may be visual, audible, or any other modality, and may be presented by the controller 212, 312 and/or transmitted to a remote device 220, 320. In some embodiments, in block 516 the controller 212, 312 may activate an automatic water or chemical addition based on the sensor data. For example, in response to determining that the percentage propylene glycol in the coolant is below the predetermined acceptable range (e.g., below about 90 wt. %, below about 80 wt. %, below about 70 wt. %, below about 60 wt. %, below about 50 wt. %, below about 40 wt. %, below about 30 wt. %, below about 20 wt. %, below about 10 wt. %, or below about 5 wt. %), the controller 212, 312 may cause additional propylene glycol to be added to the coolant by one or more chemical injection pumps or other components. The chemical may be added at an addition point in the coolant blade 302, the CDU 104, or another addition point, such as to TCS 108 and/or a conduit of manifold 124.

In some embodiments, the controller 212, 312 may cause the addition of other chemicals. For example, in response to detecting microbiology activity in the coolant, the controller 212, 312 may cause addition of biocide or other microbe inhibitor. As another example, in response to determining that the percentage propylene glycol in the coolant is above the predetermined acceptable range, the controller 212, 312 may cause additional water to be added to the coolant.

As another example, the controller 212, 312 may cause the secondary loop to be refilled (e.g., with water, a glycol, or a mixture thereof) in response to detecting a compute blade 120 change. Continuing that example, in some embodiments, the compute blade 120 may be stored with its internal cooling passages empty or otherwise with less coolant than used in operation. In such embodiments, replacing an operating compute blade 120 with another compute blade 120 may reduce the total amount of coolant in the secondary loop 108. As described herein, the controller 212, 312 may cause replenishment of the coolant based on measured sensor data and/or received user input (e.g., a buttonpress or other input indicating that a compute blade 120 has been changed). As another example, the controller 212, 312 may detect a compute blade 120 change based on sensor data, such as changes in pressure and flow rate at the pump outlet (e.g., in the CDU 104).

In some embodiments, control operations performed by the controller 212, 312 may include optimization of one or more properties of the coolant. Optimization can include, for example, measuring one or more properties associated with the coolant to be sure that the one or more properties are within an acceptable, predetermined range and, if the one or more properties are not within the acceptable, predetermined range for each respective property being measured, causing a change in the coolant to bring the property back within the acceptable, predetermined range. As another example, in some embodiments, the controller 212, 312 may cause discharge of at least a portion of the coolant in the secondary loop 108 and then replenish the secondary loop 108 with fresh fluid, for example when sensor data indicates potential contamination of the coolant.

The presently disclosed system 200, 300 comprises, in certain embodiments, one or more chemical injection pumps. Each chemical injection pump may be in fluid communication with a storage device. Each storage device may comprise one or more chemicals and the chemical injection pumps may transport those chemicals into the secondary loop 108 of coolant. In some embodiments, the chemical injection pump comprises the storage device. The chemical injection pumps may be in communication with the controller 212, 312 in any number of ways, such as through any combination of wired connection, a wireless connection, electronically, cellularly, through infrared, satellite, or according to any other types of communication networks, topologies, protocols, standards and more. Accordingly, the controller 212, 312 can send signals to the pumps to control their chemical feed rates.

The system 200, 300 and/or controller 212, 312 disclosed herein can incorporate programming logic to convert analyzer signals from the plurality of sensors 210, 310 to pump adjustment logic and, in certain embodiments, control one or more of a plurality of chemical injection pumps with a unique basis. Non-limiting, illustrative examples of the types of chemical injection pumps that can be manipulated include chemical injection pumps responsible for injecting biocides, scale inhibitors, corrosion inhibitors, friction reducers, acids, bases, sulfites, oxygen scavengers, dispersants, scouring agents, viscosity modifiers, heat transfer additives, surfactants, and/or any other type of chemical/additive that could prove to be useful in the particular aqueous industrial system.

Illustrative examples of biocides include bronopol, gluteraldehyde, tetrakis(hydroxymethyl)phosphonium sulphate, a quaternary ammonium compound, chlorine, hypochlorite, ClO₂, bromine, ozone, hydrogen peroxide, peracetic acid, peroxycarboxylic acid, peroxysulphate, dibromonitrilopropionamide, isothiazolone, terbutylazine, polymeric biguanide, methylene bisthiocyanate, and any combination thereof.

Additional examples include a 2,2-dibromo-3-nitrilopropionamide (DBNPA)-based biocide, 5-chloro-2-methyl-3-isothiazolone, 2-methyl-3-isothiazolone, 2-bromo-2-nitro-1,3-propanediol, and any combination thereof.

A scale inhibitor may include, for example, a phosphonate, a sulfonate, a phosphate, a phosphate ester, a polymer comprising a phosphonate or phosphonate ester group, a polymeric organic acid, a peroxycarboxylic acid, and any combination thereof. In some embodiments, the scale inhibitor may be selected from a compound comprising an amine and/or a quaternary amine, nitrilotriacetic acid (NTA), ethylenediaminetetraacetic acid (EDTA), DETA phosphonate, and any combination thereof.

In some embodiments, the scale inhibitor is an acid-based scale inhibitor, such as phosphonic acid. In some embodiments, the scale inhibitor comprises an anionic group. The anionic group may comprise, for example, a carboxylate group or a sulfate group. In some embodiments, the scale inhibitor may include a phosphorous atom, a phosphorous-oxygen double bond, and/or a phosphono group.

In some embodiments, the scale inhibitor is selected from the group consisting of hexamethylene diamine tetrakis (methylene phosphonic acid), diethylene triamine tetra (methylene phosphonic acid), diethylene triamine penta (methylene phosphonic acid), polyacrylic acid (PAA), phosphino carboxylic acid (PPCA), diglycol amine phosphonate (DGA phosphonate), 1-hydroxyethylidene 1,1-diphosphonate (HEDP phosphonate), bisaminoethylether phosphonate (BAEE phosphonate), 2-acrylamido-2-methyl-1-propanesulphonic acid (AMPS), and any combination thereof.

In certain embodiments, the scale inhibitor is a polymer comprising an anionic monomer. The anionic monomer may be selected from, for example, acrylic acid, methacrylic acid, vinyl sulfonic acid, vinyl phosphonic acid, maleic anhydride, itaconic acid, crotonic acid, maleic acid, fumaric acid, styrene sulfonic acid, and any combination thereof.

The acid may comprise, for example, hydrochloric acid, hydrofluoric acid, sulfuric acid, citric acid, formic acid, acetic acid, or any combination thereof.

The base may comprise, for example, sodium hydroxide, potassium hydroxide, lithium hydroxide, ammonia, sodium bicarbonate, or any combination thereof.

The corrosion inhibitor may comprise, for example, an imidazoline compound, a pyridinium compound, a quaternary ammonium compound, a phosphate ester, an amine, an amide, a carboxylic acid, a thiol, and any combination thereof.

In some embodiments, the corrosion inhibitor comprises a benzotriazole compound and/or a derivative thereof, a halo-benzotriazole, a imidazole compound, a benzimidazole compound, a substituted imidazole compound, a substituted benzimidazole compound, a tetrazole compound, a pyrazole compound and/or a derivative thereof, a pyrimidine compound and/or a derivative thereof, and any combination thereof.

The surfactant may be non-ionic, cationic, anionic, amphoteric, or zwitterionic.

The friction reducer may include, for example, a dispersion polymer, wherein the dispersion polymer comprises from about 5 to about 95 mole percent of one or more nonionic monomers and from about 95 to about 5 mole percent of one or more cationic and/or anionic monomers.

A “dispersion polymer” is a water-soluble polymer dispersed in an aqueous continuous phase containing one or more inorganic salts (e.g., ammonium sulfate, magnesium sulfate, sodium chloride, etc.). The dispersion polymer may exclude an organic solvent and/or a surfactant.

In some embodiments, the dispersion polymer comprises from about 95 to about 50 mole percent of a nonionic monomer and from about 95 to about 50 mole percent of one or more cationic monomers selected from the group consisting of dialkylaminoalkyl (meth) acrylates, quaternary or acid salts thereof, dimethylaminoethyl acrylate methyl chloride quaternary salt, dimethylaminoethyl acrylate benzyl chloride quaternary salt, and any combination thereof.

In some embodiments, the dispersion polymer is acrylamide/dimethylaminoethyl acrylate methyl chloride quaternary salt/dimethylaminoethyl acrylate benzyl chloride quaternary salt terpolymer or acrylamide/dimethylaminoethyl acrylate methyl chloride quaternary salt copolymer.

In some embodiments, the dispersion polymer comprises from about 95 to about 50 mole percent of a nonionic monomer and from about 95 to about 50 mole percent of an anionic monomer selected from the group consisting of acrylic acid, methacrylic acid, 2-acrylamido-2-methylpropanesulfonic acid, a salt thereof, and any combination thereof.

Illustrative examples include an acrylamide/acrylic acid sodium salt copolymer, an acrylamide/acrylic acid copolymer, and an acrylamide/acrylic acid/acrylic acid sodium salt terpolymer.

“Anionic monomer” means a monomer possessing a negative charge. Representative anionic monomers include (meth)acrylic acid, and it's salts, including, but not limited to acrylic acid, sodium acrylate, ammonium acrylate, methacrylic acid, sodium methacrylate, and ammonium methacrylate; 2-acrylamido-2-methylpropanesulfonic acid (AMPS) and its sodium salt; vinyl sulfonic acid and its salts including sodium vinyl sulfonate; styrene sulfonic acid and its salts; maleic acid and it's salts, including, but not limited to the sodium salt and ammonium salt; sulfopropyl acrylate or methacrylate or other water-soluble forms of these or other polymerisable carboxylic or sulphonic acids; sulfomethylated acrylamide; allyl sulfonate; itaconic acid, acrylamidomethylbutanoic acid; fumaric acid; vinylphosphonic acid; allylphosphonic acid, phosphonomethylated acrylamide, and the like.

“Cationic Monomer” means a monomer possessing a positive charge. Representative cationic monomers include dialkylaminoalkyl acrylates and methacrylates and their quaternary or acid salts, including, but not limited to, dimethylaminoethyl acrylate methyl chloride quaternary salt, dimethylaminoethyl acrylate methyl sulfate quaternary salt, dimethyaminoethyl acrylate benzyl chloride quaternary salt, dimethylaminoethyl acrylate sulfuric acid salt, dimethylaminoethyl acrylate hydrochloric acid salt, diethylaminoethyl acrylate, methyl chloride quaternary salt, dimethylaminoethyl methacrylate methyl chloride quaternary salt, dimethylaminoethyl methacrylate methyl sulfate quaternary salt, dimethylaminoethyl methacrylate benzyl chloride quaternary salt, dimethylaminoethyl methacrylate sulfuric acid salt, dimethylaminoethyl methacrylate hydrochloric acid salt, dimethylaminoethyl methacryloyl hydrochloric acid salt, dialkylaminoalkylacrylamides or methacrylamides and their quaternary or acid salts such as acrylamidopropyltrimethylammonium chloride, dimethylaminopropyl acrylamide methyl sulfate quaternary salt, dimethylaminopropyl acrylamide sulfuric acid salt, dimethylaminopropyl acrylamide hydrochloric acid salt, methacrylamidopropyltrimethylammonium chloride, dimethylaminopropyl methacrylamide methyl sulfate quaternary salt, dimethylaminopropyl methacrylamide sulfuric acid salt, dimethylaminopropyl methacrylamide hydrochloric acid salt, diethylaminoethylacrylate, diethylaminoethylmethacrylate and diallyldialkylammonium halides such as diallyldiethylammonium chloride and diallyldimethyl ammonium chloride.

“Nonionic monomer” means a monomer that is electrically neutral. Representative non-ionic, water-soluble monomers include acrylamide, methacrylamide, N-methylacrylamide, N,N-dimethylacrylamide, N,N-diethylacrylamide, N-isopropylacrylamide, N-vinylformamide, N-vinylmethylacetamide, dimethylhydroxypropyl (meth)acrylate, hydroxyethyl methacrylate, hydroxyethyl acrylate, hydroxypropyl acrylate, hydroxypropyl methacrylate, N-t-butylacrylamide, N-methylolacrylamide, vinyl acetate, acrylonitrile, 2-ethylhexyl acrylate, and the like.

The amount of additive/chemical added to the coolant is not particularly limited. In some embodiments, the amount of chemical added is from about 1 ppm to about 10,000 ppm, such as about 1 ppm to about 5,000 ppm, about 1 ppm to about 2,500 ppm, about 1 ppm to about 1,500 ppm, about 1 ppm to about 1,000 ppm, about 1 ppm to about 750 ppm, about 1 ppm to about 500 ppm, about 1 ppm to about 250 ppm, about 1 ppm to about 100 ppm, about 25 ppm to about 5,000 ppm, about 25 ppm to about 2,500 ppm, about 25 ppm to about 1,500 ppm, about 25 ppm to about 1,000 ppm, or about 25 ppm to about 500 ppm.

After performing one or more control operations, the method 500 loops back to block 502 to continue monitoring sensor data from the sensors 210, 310. The method 500 is optionally repeated for a plurality of different system parameters, where each different system parameter has a unique associated property, or, alternatively, all system parameters can be analyzed concurrently by the plurality of sensors 210, 310.

As used herein, the term “controller” refers to a manual operator or an electronic device having components, such as a processor, memory device, digital storage medium, a communication interface including communication circuitry operable to support communications across any number of communication protocols and/or networks, a user interface (e.g., a graphical user interface that may include cathode ray tube, liquid crystal display, plasma display, touch screen, or other monitor), and/or other components.

The controller is preferably operable for integration with one or more application-specific integrated circuits, programs, computer-executable instructions or algorithms, one or more hard-wired devices, wireless devices, and/or one or more mechanical devices. Moreover, the controller is operable to integrate the feedback, feed-forward, and/or predictive loop(s) of the invention. Some or all of the controller system functions may be at a central location, such as a network server, for communication over a local area network, wide area network, wireless network, internet connection, microwave link, infrared link, wired network (e.g., Ethernet) and the like. In addition, other components, such as a signal conditioner or system monitor, may be included to facilitate signal transmission and signal-processing algorithms.

In certain aspects, the controller includes hierarchy logic to prioritize any measured or predicted properties associated with system parameters. For example, the controller may be programmed to prioritize percentage glycol over conductivity, or vice versa. It should be appreciated that the object of such hierarchy logic is to allow improved control over the system parameters and to avoid circular control loops.

As described above, the system 200, 300, 600 may comprise a plurality of sensors, which are capable of analyzing the coolant and transmitting data regarding the coolant to the controller. In certain embodiments, the system is implemented to have the plurality of sensors provide continuous or intermittent feedback, feed-forward, and/or predictive information to the controller, which can relay this information to a relay device, such as the Nalco Global Gateway, which can transmit the information via cellular communications to an operator, a remote device, such as a cellular telephone, computer, computer server, and/or any other device that can receive cellular communications. This remote device and/or the operator, can interpret, store, or otherwise process the information and in some embodiments may automatically send a signal (e.g. electronic instructions) back, through the relay device, to the controller to cause the controller to perform certain operations.

Alternatively, an operator of the remote device that receives cellular communications from the controller can manually manipulate the system 202, 602. The operator may communicate instructions, through the remote device, cellularly or otherwise, to the controller 212 and the controller 212 can make adjustments to the system 202. For example, the operator can receive a signal or alarm from the remote device through a cellular communication from the controller 212 and send instructions or a signal back to the controller 212. The controller and/or the remote device is also capable of making any of the foregoing adjustments or modifications automatically without the operator actually sending or inputting any instructions. Preset parameters or programs are entered into the controller or remote device so that the controller or remote device can determine if a measured property is outside of an acceptable range. Based on the information received by the plurality of sensors, the controller or remote device can make appropriate adjustments to the system 202 or send out an appropriate alert.

In certain embodiments, the remote device or controller can include appropriate software to receive data from the plurality of sensors and determine if the data indicates that one or more measured properties of the coolant are within, or outside, an acceptable range. The software can also allow the controller or remote device to determine appropriate corrective actions that should be taken to remedy the property that is outside of the acceptable range. For example, if the measured percentage of propylene glycol is below the acceptable range, the software allows the controller or remote device to make this determination and take corrective action, such as alerting a pump to inject propylene glycol into the coolant.

Alternatively, an operator of the remote device that receives cellular communications from the controller can manually manipulate the system through the remote device. The operator may communicate instructions, through the remote device, cellularly or otherwise, to the controller and the controller can make adjustments to the rate of chemical addition of the chemical injection pumps. For example, the operator can receive a signal or alarm from the remote device through a cellular communication from the controller and send instructions or a signal back to the controller using the remote device to carry out various corrective actions, such as turn on one or more of the chemical injection pumps, turn off one or more of the chemical injection pumps, increase or decrease the amount of chemical being added to the coolant, open a valve of a storage vessel to allow a chemical and/or water to flow into the coolant, close a valve of a storage vessel to block chemical and/or water from flowing into the coolant, initiate ultrasonic cleaning, introduce nanobubbles, or any combination of the foregoing. The controller and/or the remote device is also capable of making any of the foregoing adjustments or modifications automatically without the operator actually sending or inputting any instructions. Based on the information received by the plurality of sensors, the controller or remote device can make appropriate adjustments to the pumps, valves, and/or send out an appropriate alert.

The sensors disclosed herein are operable to sense and/or predict a property associated with the coolant or system parameter and convert the property into an input signal, e.g., an electric signal, capable of being transmitted to the controller. A transmitter associated with each sensor transmits the input signal to the controller. The controller is operable to receive the transmitted input signal, convert the received input signal into an input numerical value, analyze the input numerical value to determine if the input numerical value is within an optimum range, generate an output numerical value, convert the output numerical value into an output signal, e.g., an electrical signal, and transmit the output signal to a receiver, such as a remote device, such as a computer or cellular telephone, incorporating receiver capabilities. The receiver receives the output signal and alerts an operator and/or the receiver can be operable to carry out a corrective action if the output numerical value is not within the acceptable range for that property.

In accordance with certain embodiments of the present disclosure, a method of monitoring and controlling one or more properties of a medium, such as a cooling liquid comprising water and/or a glycol, is provided. The properties can be, for example, glycol wt. %, pH, conductivity, turbidity, flow, pressure, biocide concentration, particle size, entrained air, any combination thereof, etc.

In illustrative embodiments, an acceptable range of about 23 wt. % to about 29 wt. % may be set for the glycol concentration in the medium. Glycol levels may be monitored and if the level of glycol falls below about 23 wt. %, a corrective action may be taken, such as adding more glycol to the medium. If the level of glycol rises above about 29 wt. %, a corrective action may be taken, such as adding water.

In illustrative embodiments, an acceptable range of about 7.0 to about 10.5 may be set for the pH of the medium. The pH of the medium may be monitored and if the pH falls below about 7.0, a corrective action may be taken, such as adding a base. If the pH rises above about 10.5, a corrective action may be taken, such as adding an acid.

In certain embodiments, if the turbidity rises above about 100 NTU, a corrective action may be taken, such as adding water. In certain embodiments, if the amount of entrained air rises above about 2%, a corrective action may be taken, and if a particle size of greater than about 200 microns is detected, a corrective action may be taken, such as transporting the medium through a side-stream conduit containing a filter to remove the particles.

Particles in a medium of the present disclosure may comprise a variety of contaminants, such as microbiological growth, scale, dust, debris, and/or other unwanted matter in the cooling liquid. In some embodiments, dynamic light scattering may be used to determine particle size. In certain embodiments, the particle size analyzer (also referred to herein as particle size sensor) may detect particles having sizes greater than about 0.01 microns, such as greater than about 0.1 microns, e.g., 0.5 microns to about 50 microns or more. In an illustrative example, if a particle size of about 0.5 microns or greater is detected, a corrective action may be carried out, an alarm may be sent to an operator, etc.

A corrective action may include transporting the liquid coolant through a side stream comprising a filter so that the particle(s) may be removed. A corrective action may also include draining all or a portion of the liquid coolant and replacing it with new, particle-free liquid coolant. In certain embodiments, the corrective action may include draining and refilling with new liquid coolant, greater than about 1% of the total volume of coolant from the secondary coolant loop, such as greater than about 2%, greater than about 5%, greater than about 10% or more.

The method includes the use of a monitoring and controlling unit comprising a controller and a plurality of sensors in communication with the controller. Each of the plurality of sensors is operable to measure a property of the medium. For example, in some embodiments, the unit comprises three sensors, wherein each sensor is operable to measure a different property, such as wt. % glycol (e.g., propylene glycol), pH, and conductivity.

One or more pumps, which are in communication with the controller, may be utilized to inject various chemicals into the medium, such as a glycol (e.g., propylene glycol), water, a corrosion inhibitor, a biocide, a scouring agent, an acid, a base, etc. Each chemical may have its own chemical injection pump. Also, each conduit responsible for transporting the chemical into the medium may comprise a valve, which may be opened or closed, to allow or block, respectively, the flow of the chemical into the medium.

An acceptable range for each of the one or more properties of the medium to be measured is entered into the controller.

For example, an acceptable range for the weight percent of glycol in the medium may be from about 0 wt. % to about 100 wt. %, such as about 0 wt. % to about 50 wt. %, about 0 wt. % to about 25 wt. %, about 1 wt. % to about 90 wt. %, about 1 wt. % to about 50 wt. %, about 1 wt. % to about 25 wt. %, about 20 wt. % to about 100 wt. %, about 20 wt. % to about 90 wt. %, about 20 wt. % to about 80 wt. %, about 20 wt. % to about 70 wt. %, about 20 wt. % to about 60 wt. %, about 20 wt. % to about 50 wt. %, about 20 wt. % to about 40 wt. %, about 20 wt. % to about 30 wt. %, about 23 wt. % to about 100 wt. %, about 23 wt. % to about 80 wt. %, about 23 wt. % to about 60 wt. %, about 23 wt. % to about 40 wt. %, about 25 wt. % to about 90 wt. %, about 30 wt. % to about 90 wt. %, about 40 wt. % to about 90 wt. %, or about 50 wt. % to about 90 wt. %.

Similarly, an acceptable range for the weight percent of water in the medium may be from about 0 wt. % to about 100 wt. %, such as about 0 wt. % to about 50 wt. %, about 0 wt. % to about 25 wt. %, about 1 wt. % to about 90 wt. %, about 1 wt. % to about 50 wt. %, about 1 wt. % to about 25 wt. %, about 20 wt. % to about 100 wt. %, about 20 wt. % to about 90 wt. %, about 20 wt. % to about 80 wt. %, about 20 wt. % to about 70 wt. %, about 20 wt. % to about 60 wt. %, about 20 wt. % to about 50 wt. %, about 20 wt. % to about 40 wt. %, about 20 wt. % to about 30 wt. %, about 23 wt. % to about 100 wt. %, about 23 wt. % to about 80 wt. %, about 23 wt. % to about 60 wt. %, about 23 wt. % to about 40 wt. %, about 25 wt. % to about 90 wt. %, about 30 wt. % to about 90 wt. %, about 40 wt. % to about 90 wt. %, or about 50 wt. % to about 90 wt. %.

A conduit may be provided between the medium and the monitoring and controlling unit, such as FCS 108, internal liquid conduit 204, a conduit of manifold 122, etc. A sample of medium passes through the conduit and into an inlet of the monitoring and controlling unit, which comprises the sensors. Next, one or more properties of the medium are measured using the sensors and the controller determines if the measured one or more properties are within the acceptable range entered into the controller in the previous step. This determining step can be automatically performed by the controller and in this step, the measured value for each measured property is compared to the acceptable range entered for that specific property.

If the measured one or more properties are outside of the acceptable range associated with that property, the controller and/or operator of the controller may cause a change, for example, in an influx of a chemical into the medium (e.g., from a storage vessel by opening a valve, from the one or more chemical injection pumps, etc.), the chemical(s) being capable of adjusting the measured property and bringing it back within the acceptable range. The controller is operable to determine when the measured property is back within the acceptable range and subsequently turn off the chemical injection pump(s), turn on the chemical injection pump(s), close a valve, and/or open a valve.

As an illustrative example, an acceptable wt. % range for propylene glycol in the medium may be from about 1 wt. % to about 99 wt. %. If the controller determines that the wt. % increases beyond the upper limit of the acceptable range, a corrective action may be taken. For example, the controller may cause a valve to open and allow water to flow into the medium. If the controller determines that the wt. % decreases below the lower limit of the acceptable range, a corrective action may be taken. For example, the controller may cause a valve to open and allow propylene glycol to flow into the medium.

Data transmission of measured parameters or signals to remote monitoring devices, such as computers or cellular telephones, or other system components is accomplished using any suitable device, and across any number of wired and/or wireless networks, including as examples, WiFi, WiMAX, Ethernet, cable, digital subscriber line, Bluetooth, cellular technologies (e.g., 2G, 3G, Universal Mobile Telecommunications System (UMTS), GSM, Long Term Evolution (LTE), or more) etc. The Nalco Global Gateway is an example of a suitable device. Any suitable interface standard(s), such as an Ethernet interface, wireless interface (e.g., IEEE 802.11a/b/g/x, 802.16, Bluetooth, optical, infrared, radiofrequency, etc.), universal serial bus, telephone network, the like, and combinations of such interfaces/connections may be used.

As used herein, the term “network” encompasses all of these data transmission methods. Any of the described devices (e.g., archiving systems, data analysis stations, data capturing devices, process devices, remote monitoring devices, chemical injection pumps, etc.) may be connected to one another using the above-described or other suitable interface or connection.

In some embodiments, system parameter information is received from the system and archived. In certain embodiments, system parameter information is processed according to a timetable or schedule. In some embodiments, system parameter information is immediately processed in real-time or substantially real-time. Such real-time reception may include, for example, “streaming data” over a computer network.

In some embodiments, the system 200, 300, 600 may include improved sensor design elements for one or more of the sensors 210, 310. In some embodiments, one or more of the sensors 210, 310 may include connectors that simplify maintenance and calibration of the sensors 210, 310 and prevent leaks.

For example, in some embodiments, the system 200, 300, 600 may include one or more quick-connects for mounting corresponding sensors 210, 310. Continuing that example, in some embodiments, a liquid monitoring system 202 may include one or more quick-connects for mounting corresponding sensors 210. In that example, the liquid monitoring system 202 may be installed on a stand, a sled, a plate, a panel, or other physical structure such that the one or more quick-connects are accessible to a technician servicing the liquid monitoring system 202. When a sensor 210 is attached to the quick-connect, that sensor 210 is in fluid communication with the fluid conduit 204.

Similarly, in some embodiments, a coolant blade 302 may include one or more quick-connects for mounting corresponding sensors 310. In those embodiments, the quick-connects may be positioned in an accessible location, such as the front panel 408 of the blade 302 and/or positioned within the interior of the chassis 402 of the blade 302. When a sensor 310 is attached to the quick-connect, that sensor 310 is in fluid communication with the fluid conduit 412.

In some embodiments, the system 200, 300, 600 may include a separate port that allows a portable sensor 210, 310 bank to be added. The port provides access to the corresponding fluid conduit 204, 412. For example, in an embodiment, a full sensor suite may be attached to the separate port. As another example, one or more sensors 210, 310 that may be used temporarily may be attached to the separate port.

In some embodiments, the system 200, 300, 600 may include a modular sensor system. For example, in an embodiment, the sensors 210, 310 of the system 200, 300, 600 may be included in one or more modular components. Each modular component may be attached to the fluid conduit 204, 412, for example, using one or more quick-connects or other fluid connectors. Accordingly, in those embodiments, the sensors 210, 310 of the system 200, 300, 600 may be installed, replaced, serviced, upgraded, or otherwise managed as a modular component.

As an illustrative example, in certain embodiments, the three sensors 210a, 210b, 210c shown in FIG. 2 may be incorporated in a modular component that may be installed or replaced as a single unit.

In some embodiments, the system 200, 300, 600 may include calibration-free sensors 210, 310. In some embodiments, the sensors 210, 310 may be robust, long-lived sensors that are expected to operate without calibration while the system 200, 300, 600 is in service. In certain embodiments, the system 200, 300, 600 may include sensor 210, 310 elements that are disposable. The disposable sensor elements may be replaced without calibration.

In some embodiments, the system 200, 300, 600 may monitor additional fluid elements. In some embodiments, the system 200, 300, 600 may monitor color of the coolant. For example, the system 200, 300, 600 may include one or more color sensors 210, 310 (e.g., RGB color sensors, colorimeters, digital imaging sensors, etc.) capable of measuring color of the coolant and/or additives in the coolant. In some embodiments, the color of the coolant may be indicative of coolant quality, and thus the color of the coolant itself may be measured. In some embodiments, the system 200, 300, 600 may measure color of an additive in the coolant that is added to be indicative of quality (e.g., coolant degradation, pH, etc.).

In some embodiments, the system 200, 300, 600 may perform multi-point leak detection. For example, leak sensors may be distributed throughout the system 200, 300, 600, including at locations within the liquid cooling system 202 and/or the coolant blade 302, the coolant distribution unit(s) (CDUs) 104 and/or heat exchangers, the blade enclosure(s) 102, or other points within the system 200, 300, 600.

In some embodiments, the system 200, 300, 600 may use infrared (IR) sensors 210, 310 to monitor for organic contamination that may be present during the start-up and commissioning process of the data center. For example, the system 200, 300, 600 may monitor for lubricants, passivation chemistries, thermal pastes, or other organic contamination.

In some embodiments, the system 200, 300, 600 may perform real-time alkalinity monitoring, for example, using one or more pH sensors 210, 310 or other alkalinity sensors. In some embodiments, the pH sensors 210, 310 may be specialized alkalinity sensors. In certain embodiments, the system 200, 300, 600 may monitor alkalinity via an online titration. In some embodiments, the system 200, 300, 600 may monitor for air entrainment within the cooling loop 108, 208.

In some embodiments, the system 200, 300, 600 may include one or more additional sensors relating to CDU 104 performance, heat exchanger performance, and/or the performance of the computing system. Those sensors may include additional sensors 210, 310 coupled to the liquid cooling conduit 204, 412 and/or additional sensors that measuring other aspects of CDU 104 performance. Each of those additional sensors may communicate with the controller 212, 312 as described above. For example, the additional sensors monitoring CDU 104 performance may measure vibration, pressure drops over specific parts, temperatures, flow rates, and/or other performance aspects of the CDU 104. In some embodiments, the system 200, 300, 600 may use the monitored data relating to performance of the CDU 104 to predict and/or identify pump failure.

In some embodiments, the system 200, 300, 600 may measure air-side temperatures (e.g., environmental temperatures) and/or dewpoint near the CDU 104 in order to avoid undesirable condensation. In some embodiments, the system 200, 300, 600 may perform real time monitoring of the heat exchanger 140 in the CDU 104.

In some embodiments, the system 200, 300, 600 may perform additional analytics based on monitored data. In some embodiments, the system 200, 300, 600 may predict fluid life and/or predict when coolant should be replaced.

In some embodiments, the system 200, 300, 600 may monitor operational modifications to the system 200, 300, 600. For example, the system 200, 300, 600 may monitor for compute blade 120 replacement, and perform appropriate corrective actions (e.g., add make-up coolant, additives/chemicals, water, open a valve, close a valve, transport the liquid coolant through a side stream comprising a filter, etc.). As another example, the system 200, 300, 600 may monitor for filter changes.

In some embodiments, the system 200, 300, 600 may integrate coolant data with heat load requirements and modify the flow rate to deliver the appropriate cooling capacity in real time. For example, the system 200, 300, 600 may determine heat load requirements based on current computation load, in communication with the blade enclosure 102, one or more compute blades 120, a data center orchestrator, and/or other data center systems. Based on those head load requirements, the system 200, 300, 600 may communicate with the CDU 104 to provide an appropriate flow rate to achieve the cooling appropriate for the heat load requirements.

In some embodiments, the system 200, 300, 600 may use a machine learning and/or artificial intelligence (AI) powered evaluation of fluid health that uses multiple coolant characteristics to determine health of the fluid. The AI evaluation may be performed locally by the controller 212, 312, for example, using one or more lightweight pretrained models, and/or may be performed by a remote device 220, 320, including one or more remote cloud services. In some embodiments, the system 200, 300 may make recommendations on one or more types of service needed based on the monitoring data. This determination of required service may also be assisted by AI.

All of the compositions and methods disclosed and claimed herein can be made and executed without undue experimentation in light of the present disclosure. While this invention may be embodied in many different forms, there are described in detail herein specific preferred embodiments of the invention. The present disclosure is an exemplification of the principles of the invention and is not intended to limit the invention to the particular embodiments illustrated. In addition, unless expressly stated to the contrary, use of the term “a” is intended to include “at least one” or “one or more.” For example, “a glycol” is intended to include “at least one glycol” or “one or more glycols.”

Any ranges given either in absolute terms or in approximate terms are intended to encompass both, and any definitions used herein are intended to be clarifying and not limiting. Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all subranges (including all fractional and whole values) subsumed therein.

Any composition disclosed herein may comprise, consist of, or consist essentially of any element, component and/or ingredient disclosed herein or any combination of two or more of the elements, components or ingredients disclosed herein.

Any method disclosed herein may comprise, consist of, or consist essentially of any method step disclosed herein or any combination of two or more of the method steps disclosed herein.

The transitional phrase “comprising,” which is synonymous with “including,” “containing,” or “characterized by,” is inclusive or open-ended and does not exclude additional, un-recited elements, components, ingredients and/or method steps.

The transitional phrase “consisting of” excludes any element, component, ingredient, and/or method step not specified in the claim.

The transitional phrase “consisting essentially of” limits the scope of a claim to the specified elements, components, ingredients and/or steps, as well as those that do not materially affect the basic and novel characteristic(s) of the claimed invention.

Furthermore, the invention encompasses any and all possible combinations of some or all of the various embodiments described herein. It should also be understood that various changes and modifications to the presently preferred embodiments described herein will be apparent to those skilled in the art. Such changes and modifications can be made without departing from the spirit and scope of the invention and without diminishing its intended advantages. It is therefore intended that such changes and modifications be covered by the appended claims.

What is claimed is:

1. A system for computing device cooling liquid monitoring, the system comprising:
a liquid monitoring system adapted to be coupled to a secondary coolant loop, wherein the secondary coolant loop connects a high-performance computing system and a heat exchanger, wherein the liquid monitoring system comprises a liquid cooling conduit in fluid communication with the secondary coolant loop and one or more sensors fluidly coupled to the liquid cooling conduit and/or the secondary coolant loop; and
a controller operatively coupled to at least one of the one or more sensors.

2. The system of claim 1, wherein secondary coolant loop and/or the liquid cooling conduit comprise a liquid coolant.

3. The system of claim 1, further comprising a port coupled to the liquid cooling conduit, wherein the port is adapted to connect a portable bank of sensors to the liquid cooling conduit.

4. The system of claim 1, wherein the one or more sensors comprise a conductivity sensor, a turbidity sensor, a pH sensor, a temperature sensor, a flow rate sensor, a fluorometer, a color sensor, a dissolved oxygen sensor, a pressure sensor, a differential pressure sensor, a vibration sensor, an IR light sensor, an alkalinity sensor, an entrained air sensor, a particle size sensor, a sensor for measuring glycol wt. %, a microbiology sensor, an oxidation-reduction potential sensor, a device for measuring organic and/or inorganic fouling, a vibration sensor, a pressure sensor, a temperature sensor, a flow rate sensor, or any combination thereof.

5. The system of claim 1, wherein the controller is further configured to compare the sensor data to one or more predetermined sensor data values and add an additive to the secondary coolant loop in response to the comparison.

6. The system of claim 5, wherein the additive is selected from the group consisting of a corrosion inhibitor, a scale inhibitor, a buffer, a dispersant, a biocide, a scouring agent, a viscosity modifier, a heat transfer additive, a surfactant, a glycol, water, and any combination thereof.

7. The system of claim 2, wherein the controller is further configured to:
discharge a portion of the liquid coolant from the secondary coolant loop coupled to the liquid cooling conduit based on the sensor data; and
add additional liquid coolant to the secondary coolant loop in response to the discharge of the portion of the liquid coolant.

8. The system of claim 2, wherein the controller is further configured to evaluate a plurality of characteristics of the liquid coolant with an artificial intelligence model to determine health of the liquid coolant, wherein the artificial intelligence model is locally executed by the controller or remotely hosted by a remote computing device.

9. A system for computing device cooling liquid monitoring, the system comprising:
a coolant blade adapted to be received in a high-performance computing blade enclosure, the coolant blade comprising:
a pair of opposing side surfaces separated by a predetermined distance;
a liquid cooling conduit;
a liquid connector fluidly coupled to the liquid cooling conduit;
one or more sensors fluidly coupled to the liquid cooling conduit; and
a controller coupled to the sensors of the coolant blade;
wherein the liquid connector is configured to be removably coupled to a secondary coolant loop of the high-performance computing blade enclosure when the coolant blade is received in the high-performance computing blade enclosure; and
wherein the controller is configured to receive sensor data indicative of one or more properties of a liquid coolant within the liquid cooling conduit from the one or more sensors.

10. The system of claim 9, wherein the liquid cooling conduit is mounted to the coolant blade and/or wherein the coolant blade further comprises a first panel that separates the side surfaces and the liquid connector is mounted to the first panel.

11. The system of claim 9, wherein the liquid connector comprises an inlet connector and an outlet connector, and wherein when the coolant blade is received in the high-performance computing blade enclosure, the inlet connector is fluidly coupled to a supply manifold of the high-performance computing blade enclosure and the outlet connector is fluidly coupled to a return manifold of the high-performance computing blade enclosure.

12. The system of claim 9, wherein the controller is further configured to detect a coolant blade change based on the sensor data.

13. The system of claim 12, wherein the controller is further configured to add additional liquid coolant to the secondary coolant loop and/or discharge at least a portion of the liquid coolant from the secondary coolant loop in response to detection of the coolant blade change.

14. The system of claim 9, wherein the controller is further configured to compare the sensor data to one or more predetermined sensor data values.

15. The system of claim 9, wherein the controller is further configured to activate an alarm and/or add an additive to the secondary coolant loop in response to comparison of the sensor data to the one or more predetermined sensor data values.

16. A method of monitoring and controlling a property of a medium, comprising:
(a) providing a monitoring and controlling unit comprising a controller and a sensor in communication with the controller, wherein the sensor is operable to measure a property of the medium selected from the group consisting of weight % glycol, pH, and conductivity;
(b) providing a chemical injection pump, which is in communication with the controller;
(c) entering an acceptable range for the property into the controller;
(d) providing a delivery conduit having a first end in fluid communication with the medium and a second end in fluid communication with an inlet of the monitoring and controlling unit;
(e) delivering a sample of the medium through the delivery conduit to the monitoring and controlling unit;
(f) measuring the property in the sample with the sensor;
(g) determining if the measured property is within the acceptable range entered into the controller in step (c);
(h) carrying out a corrective action if the measured property is outside of the acceptable range entered into the controller in step (c); and
(i) optionally repeating steps (a) to (h) to determine if the property has been brought within the acceptable range entered in step (c).

17. The method of claim 16, wherein the corrective action comprises adding an additive into the medium, opening a valve, closing a valve, or any combination thereof.

18. A computing device, comprising:
a processor; and
a memory having stored therein a plurality of instructions that when executed by the processor cause the computing device to perform the method of claim 16.

19. One or more machine readable storage media comprising a plurality of instructions stored thereon that in response to being executed result in a computing device performing the method of claim 16.

20. A computing device comprising means for performing the method of claim 16.
